(19) United States
(12) Patent Application Publication
(10) Pub. No.: US 2011/0121083 A1
(43) Pub. Date: May 26, 2011

(54) DEVICE HAVING AN RFID TRANSPONDER IN AN ELECTRICALLY CONDUCTIVE OBJECT AND METHOD FOR PRODUCING SAID DEVICE

(75) Inventors: Rolf Voigtlaender, Hartha (DE); Henrik Bufe, Dresden (DE); Hans-Peter Monser, Dresden (DE); Volker Poenitz, Dresden (DE)

(73) Assignee: Muhlbauer AG, Roding (DE)

(21) Appl. No.: 12/919,742

(22) PCT Filed: Mar. 4, 2009
(86) PCT No.: PCT/EP2009/052538

§ 371 Date: Dec. 28, 2010

(30) Foreign Application Priority Data
Mar. 6, 2008 (DE) 10 2008 013 076.1
Sep. 27, 2008 (DE) 10 2008 049 371.6

(51) Int. Cl. G06K 19/077; H05K 3/20; H05K 3/00

(52) U.S. Cl. 235/492; 29/831; 29/593

(57) ABSTRACT

The invention concerns an RFID transponder device with at least one substrate and at least one RFID chip, with at least one electrically conductive first surface element, which is at a distance from the substrate and connected electrically to the substrate and/or the RFID chip by means of at least one electrically conductive first connecting element.

The device concerns a device with at least one RFID transponder, which includes at least one RFID chip, and a method for producing said device, according to the pre-characterizing clauses of Claims 1 and 9.

So-called RFID technology is used for contactless identification of a very wide variety of products. For this purpose, the products carry with them so-called transponders, which can communicate via a contactless connection with so-called readers. The transponders can consist of RFID (radio frequency identification) control electronics and if required an antenna connected to them.

The RFID control electronics can be present as an integrated circuit, which in its smallest form can be mounted on connection points of the antenna as a so-called chip, directly from a wafer based on silicon.

Such transponders are either provided with a power supply, e.g. a battery, to form a so-called active transponder, or alternatively supplied via the electrical charge of a capacitor, which is charged via the electromagnetic or magnetic field of the reader, in the integrated circuit. This type of transponder is called a passive transponder.

Communication with and power or energy supply to passive transponders function without contact with the reader below a maximum distance between the reader and the transponder.

The maximum possible distance between the transponder and the reader, at which functionality of the contactless communication is still ensured, depends on the electrical and/or magnetic field strength which is available at the location of the transponder.

As transmission frequencies for contactless communication, in RFID technology carrier frequencies of 13.56 MHz in the so-called HF (high frequency) frequency range, and 865-965 MHz in the so-called UHF (ultra high frequency) range, are standardised for world-wide use. In the UHF range, 2.46 GHz can also be used as a carrier frequency.

In the HF range of RFID technology, if a carrier frequency of 13.56 MHz is used, the wavelength of the electromagnetic waves in the air medium is about 22 m. In RFID applications, communication between the transponder and the reader takes place within a distance of up to one metre between the reader and the transponder.

Usually, when carrier frequencies in the HF range are used, the HF transponder antenna and the RFID reader antenna are coupled magnetically to each other. Consequently, the antennas which are used as coils must be in a form with few windings.

In the UHF frequency range, in contrast, in RFID technology until now a contactless connection has been set up between the UHF transponder and the UHF reader in the so-called far field, with a distance of up to several metres. Since the electromagnetic waves in the UHF range are propagated electromagnetically in the far field, UHF transponder antennas and reader antennas are usually implemented using a λ/2 dipole. If a UHF carrier frequency of 865 MHz is used, the result is a wavelength of 35 cm in the air medium.

In the UHF range of RFID technology, a near field is below a few centimetres of distance between the UHF transponder and the UHF reader. In the near field, in principle coupling between the reader and the RFID transponder can take place via the E field (capacitive) or the H field (inductive, magnetic). In the far field, electromagnetic wave propagation then takes place.

If RFID technology is used in an environment with electrically conductive objects such as metal plates or conducting foils, screening and reflection effects occur, and can make fault-free functioning of transponders difficult or prevent it completely.

However, there are fields in which the advantages of RFID technology should be used even in metallic environments, i.e. with electrically conductive objects, but because of the physical conditions cannot be used, or can be used only to a limited extent. For example, RFID technology could be wanted in military or security applications, e.g. weapons, in logistics, e.g. for metal containers, or in the case of specific packaging with electrically conductive surfaces, e.g. metal foils and metallisation on plastic surfaces.

Until now, it has not been possible to use RFID systems in the UHF range in environments with electrically conductive surfaces, e.g. in the case of contactless communication through a metallic wall, since the electromagnetic waves are up to 100% reflected, and thus controlled propagation of electromagnetic waves is prevented. In the case of UHF frequencies, it is also necessary to allow for the influence of the material thickness of the electrically conductive surface. Here it can be said in principle that the higher the frequency is, the thinner a conductive layer such as a metallic wall can be so that the electromagnetic wave can be reflected without loss (skin effect).

Thus until now, transmission of UHF frequencies through an electrically conductive wall has been impossible.

It is thus the object of the invention to make available an RFID transponder device with at least one substrate and one RFID chip, and a production method for it, with which device and method contactless communication by the RFID transponder through an electrically conductive element is possible.

This object is achieved, on the device side, by the features of Claim 1, and on the method side, by the features of Claim 9, and also in the form of a functional test to be made available.

The core idea of the invention is that in the case of an RFID transponder device with at least one substrate and at least one RFID chip, at least one electrically conductive first surface element, which is at a distance from the substrate and connected electrically to the substrate by means of at least one electrically conductive first connecting element, is arranged. The substrate can be connected electrically to the surface element via its in particular the chip connection surfaces. This also applies to the electrical connection to at least one further second surface element, which is also at a distance from the substrate and also electrically conductive. The second surface element is connected electrically to the substrate by means of at least one electrically conductive second connecting element, the second surface element being electrically insulated from the first surface element by means of at least one insulating element. In this way, for example, if the second surface element is in the form of part of an object, such as a coin which consists of electrically conductive material and at least partly envelops the substrate and the RFID chip, and if the first surface element is in the form of a cover for a recess within the object, the substrate with the RFID chip being arranged in said recess, a device which as an object of at least partly electrically conductive material makes contactless communication between the thus obtained RFID transponder and an external reader possible, can be created. A traditionally installed antenna, which is connected to the chip, is thus unnecessary. “Transponder” is understood to be a substrate with the chip and the first and second surface elements as the antenna.

For this purpose, the reader is equipped with at least one third and one fourth surface element, the third surface element being at a first distance from the first surface element, to form a capacitive coupling between the surface elements, and the fourth surface element being at a second distance from the second surface element, to form a capacitive coupling between these surface elements.

Ideally, all surface elements are in flat form, so that they stand opposite each other like plate capacitors, that is on the one hand the first and third surface elements and on the other hand the second and fourth surface elements. In this way, the capacitive coupling for contactless transmission of data by means of the reader and RFID transponder is obtained, by an electrically conductive surface such as a metallic wall of a metal housing or parts of a coin being arranged between the RFID transponder and the capacitor surfaces of the reader, and acting as a capacitor surface.

Such a device is suitable, in particular, for RFID transponders and readers which communicate with each other in the UHF range. In the far field range, in which UHF transponders are used and electromagnetic waves act as the transmission medium, because of the reflection of the waves on the electrically conductive layer, which can be an outer wall of the object, transmission is impossible, whereas transmission of data which, for example, are stored in the chip of the RFID transponder, can be implemented in the near field.

The object according to the invention is thus successful in that actual transmission in the UHF frequency range and with capacitive coupling between the RFID transponder and the reader is carried out. Here it is also shown to be advantageous that when UHF RFID transponders are used, the required components can be in small form. This, with compact construction of the RFID transponder and also of the capacitively acting surfaces of the reader, makes it possible to use such a device even for small objects such as coins. The coins which are equipped with such a device can thus be checked to be genuine, for example, by a reading process.

According to a preferred embodiment, the first and/or the second connecting element have an inductively and/or capacitively acting circuit. This can be a matching circuit, which is used to match an electrical terminal impedance of the RFID chip to the connected remaining circuit in the form of elements for capacitive coupling, the reader and further electronic components such as capacitors if any. The matching circuit is usually activated for optimal power transmission and for the required frequency characteristic of the whole system or whole device, and its parameters are dimensioned accordingly.

Advantageously, a method for producing such an RFID transponder device, with at least one substrate and at least one RFID chip, the substrate and RFID chip being arranged in or on an object, has the following steps:
arranging a substrate on or in an object;
electrically connecting the first connection surface, which is arranged on the substrate and connected to the first chip connection surface, to the electrically conductive surface element—which is at a distance from the substrate—of the object, and
electrically connecting the second connection surface, which is arranged on the substrate and connected to the second chip connection surface, to the electrically conductive second surface element—which is at a distance from the substrate—of the object.

A further step can be arranging an inductively and/or capacitively acting circuit on the substrate, the circuit being connected electrically to the first chip connection surface and the first connection surface of the substrate.

Between the first and second surface elements, at least one electrically insulating element is arranged.

In a further subsequent step, the functionality of the assembly of the RFID transponder and the first and second surface elements can be tested by means of a reader for reading the data stored on the RFID chip. To do this, it is not necessary to read out data, but, for example, only to test a current transmittance of the RFID transponder. The reader is connected to at least one third surface element and at least one fourth surface element.

The third surface element is at the first distance from the first surface element, to form a capacitive coupling together in this way. The fourth surface element is similarly at the second distance from the second surface element, to form another capacitive coupling in this way.

Further advantageous embodiments are given in the subclaims.

The advantages and usefulness can be taken from the following description, in association with the drawings.

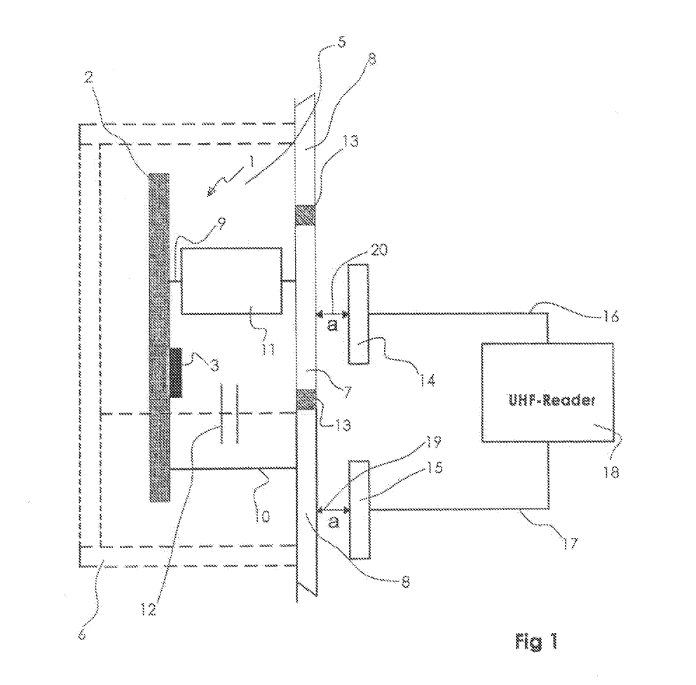

FIG. 1 shows, in a schematic representation, the structure of the device according to the invention, according to a first embodiment of the invention;

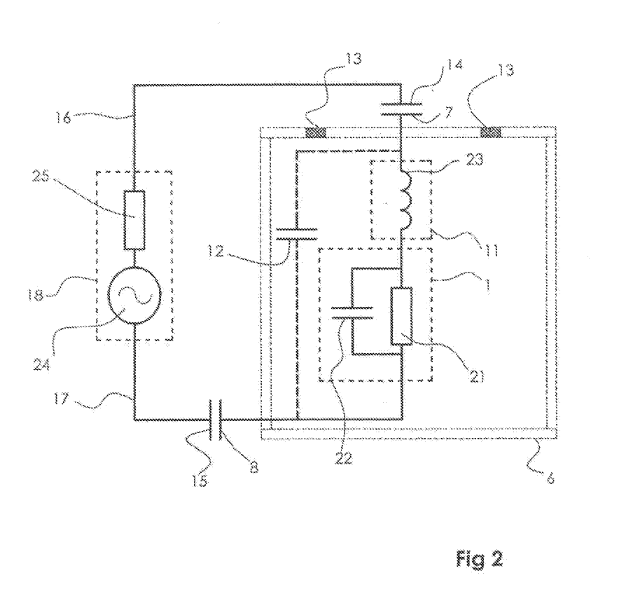

FIG. 2 shows, in a simple representation, a circuit on which the device according to the invention could be based;

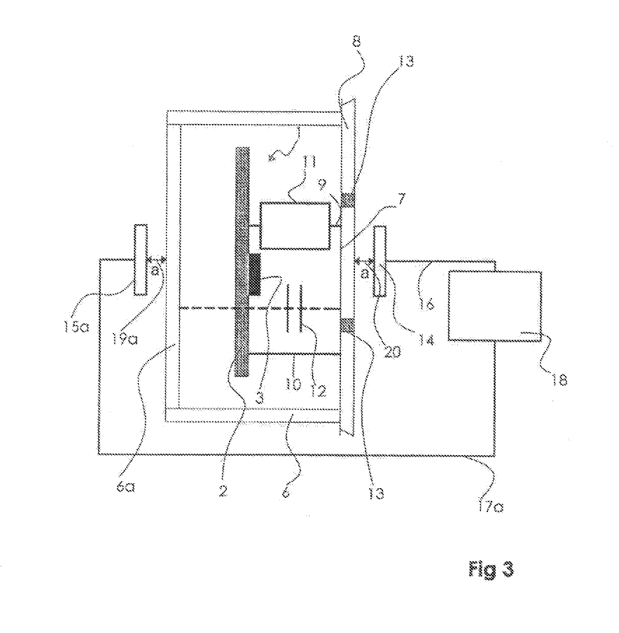

FIG. 3 shows, in a schematic representation, the structure of the device according to the invention, according to a second embodiment of the invention;

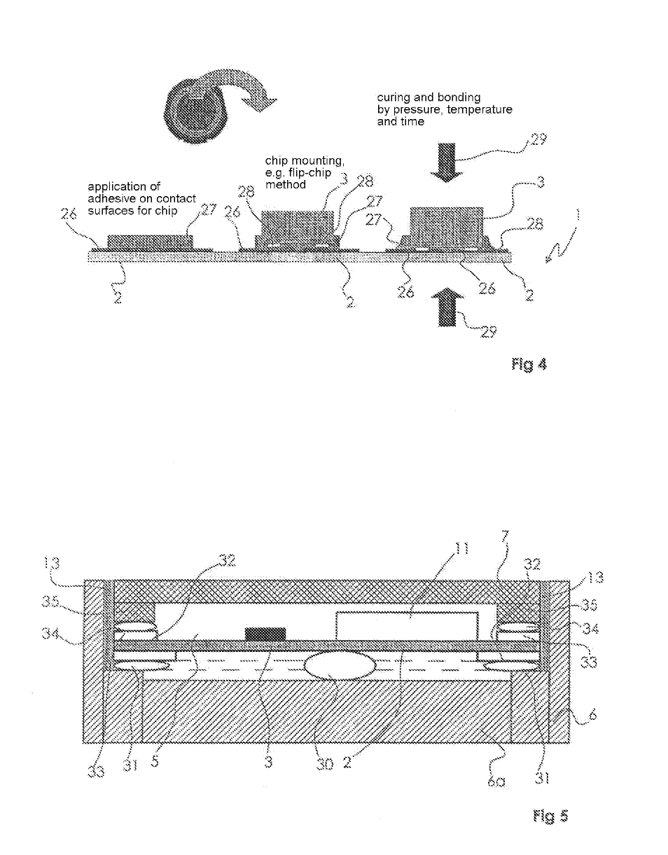

FIG. 4 shows, in a simple representation, a section of the production method according to the invention; and

FIG. 5 shows, in a cross-section representation, the structure of a coin containing the device according to the invention.

In FIG. 1, in a schematic representation, the device according to the invention is shown according to a first embodiment of the invention. An RFID transponder 1, which preferably works in the UHF frequency range, has a substrate 2 and an RFID chip 3.

The substrate portion of the RFID transponder 1 is arranged within a recess 5 of an object 6-8, which can be a coin, for example.

A first surface unit 7, which also represents a cover of the remaining coin body 6, is opposite a second surface unit 8 of annular form. It should be noted that this representation can be a cross-section through a circular coin, with insulating elements 13, which can represent an electrically insulating ring, electrically insulated.

A first connecting line 9 runs from the RFID transponder 1 to the first surface element 7, and a second connecting line 10 runs from the RFID transponder 1 to the second surface element 8.

The first connecting line 9 can have in its course a matching circuit 11, which is used to match the electrical terminal impedance of the chip 3 to the whole remaining circuit to be connected, as shown in more detail in FIG. 2. The matching circuit is optimally dimensioned with appropriate parameters for optimal power transmission and for the required frequency characteristic of the whole structure.

The first and second surface elements are electrically conductive surfaces such as coins usually have.

A third surface element 14 is separated from the first surface element 7 by a first gap 20. A fourth surface element 15 is similarly separated from the second surface element 8 by a second gap 19. The result of the surfaces, which are opposite each other, of the first and third surface elements, and of the second and fourth surface elements, and their preferably parallel alignment to each other, is arrangements like plate capacitors, which can be used to set up a capacitive coupling between the surface elements, which consist of electrically conductive material. The result of this is that by means of the capacitive coupling, a reader 18, which is connected to the third and fourth surface elements 14, 15, works in the UHF range, and is connected by the connecting lines 16, 17, can carry out contactless communication, e.g. for data transmission, with the chip 3 and thus the RFID transponder. The first connecting line 9 is connected to a first connection surface of the chip 3 or a further first connection surface, which is connected to these first connection surfaces, on the substrate, and the second connecting line 10 is connected to a second connection surface of the chip 3 or a further second connection surface, which is arranged on the substrate and connected to these second connection surfaces.

The first surface element 1 can be a cutout, e.g. in the form of a mechanically broken-out section, of the greater electrically conductive second surface element. What is decisive here is that the two surface elements or electrically conductive layers are insulated electrically from each other.

The surface elements 7, 8, 14 and 15 can, for example, be metal plates in electrically conductive form. The gaps 19, 20, and if appropriate the bases of the surface elements in the form of capacitors, affect the effective coupling of the reader to the RFID transponder, and thus the stable functioning of transmission of data between the RFID transponder 1 and the reader 18.

The form of the coin body 16, shown with a dashed line, is intended to show that the device according to the invention is capable of functioning even without the parts which are shown with a dashed line, i.e. only with the surface units 7 and 8, the result of which is only one wall of electrically conductive material, said wall being arranged between the RFID transponder 1 and the reader 18 with the associated surface elements 14, 15.

If according to the dashed line the second surface element 8 is parts of a housing 6, a capacitor 12 can be additionally arranged to form a circuit capacitor.

In FIG. 2, in a simple representation, a circuit of the device according to the invention is shown. Equal components and components with equal meaning are given equal reference symbols.

From the representation, it can be seen that in a housing 6, which for example can be a coin body, the RFID transponder 1 is arranged with a chip, it being possible to represent the transponder as electronic components by means of a resistor 21 and a capacitor 22.

Additionally, the matching circuit 11 is arranged in the coin body 6 for inductive matching. For a parasitic circuit capacitor, the capacitor 12 is connected parallel to the matching circuit and the RFID transponder 1.

The capacitive coupling which is built up between the first and third surface elements 7, 14 is represented by a capacitor. Similarly, the capacitive coupling between the second and fourth surface elements 8, 15 is represented by a capacitor. Both capacitors are connected by the connecting lines 16, 17 to the UHF reader 18, which includes a power supply 24 and a resistor 25.

In FIG. 3, the structure of the device according to the invention is shown according to a second embodiment of the invention. This representation shows that a housing or a coin body 6, which has the second surface element 8 as a part, can be involved. Equal components and components with equal meaning are given equal reference symbols.

According to a second embodiment of the invention, such a completely closed metal housing 6 of electrically conductive material makes it possible to arrange the fourth surface element 15a with a gap 19a to the underside 6a or rear wall 6a of the coin body 6, the result being an arrangement of the whole coin body 6, with the RFID transponder 1 arranged in it, between the two surface elements 14, 15a of the reader 18. Consequently, a reader with its plate elements 14, 15a acting like a capacitor can easily be placed on the top or underside of a coin.

FIG. 4 shows a section of a method according to the invention for the device according to the invention. Equal components and components with equal meaning are given equal reference symbols.

On a substrate 2, contact surfaces 26 are arranged. First, a quantity of adhesive 27 is applied to the contact surfaces, so that next an RFID chip 3, with chip connection surfaces 28 under it, can be applied to the substrate 2, preferably by means of a flip process from a chip wafer. The chip is thereby joined by permanent adhesion to the connection surfaces 26, and thus to the inlet substrate 2, by means of the previously applied adhesive mass 27. The connection surfaces 26 can be separately arranged connection surfaces of the substrate 2.

The adhesive mass can be, for example, an anisotropic adhesive (ACA adhesive), which makes an electrical connection between the RFID chip connections and the substrate connections 26 possible.

Next, when pressure is applied, curing and bonding by the effect of temperature for a suitable time take place, and a connection between the chip connection surfaces 28 and the substrate connection surfaces 26 takes place. This is shown by the double arrows 29.

Alternatively, the connection between the substrate contact surfaces or substrate connection surfaces and the chip connection surfaces 28 can be made by means of a soldered joint or a self-conducting paste such as an isotropic paste.

The previously described matching circuit 11 can be integrated on the RFID inlet substrate 2 by implementing it as part of the substrate. This can be done, for example, by the matching circuit or further electronic components for desired inductance and/or capacitance effects being in the form of so-called strip transmission lines via track geometries.

The RFID chip, after being mounted on the inlet substrate 2, can be protected from environmental effects by being encapsulated in a suitable plastic material.

The RFID inlet substrate 2 can consist of a rigid or flexible line carrier material.

As a further step in the production method according to the invention, the inlet connection surfaces 26 are connected electrically to the surface elements 7, 8. In this case the electrical connections between the substrate connection surfaces 26 and the electrically conductive layers or surface elements 7, 8 can be created by means of various connection processes. Depending on the properties of the materials to be contacted, of their surfaces and of the mechanical construction which is aimed at, electrical connection by soldering, welding, crimping, screwing or similar can be chosen.

Similarly, suitable conductive pastes and adhesive masses can produce mechanical fixing and an electrically conductive connection. For this purpose, epoxy adhesives and silver conductive pastes are suitable, for example.

In a further step, a functional test of the RFID transponder (RFID inlet), which is arranged within the electrically conductive object, e.g. a coin, takes place. For this purpose, a UHF reader, which is coupled to the outer surfaces of the coins by means of the capacitive coupling with its third and fourth surface elements 14, 15, is used, but a gap between the surface elements 7, 14 and 8, 15 is retained. In this way the function of the RFID transponder can be carried out without contact and without restriction of the specified RFID functions. It is important that the gaps 19, 19a and 20 are maintained with a previously determined optimised order of magnitude.

In FIG. 5, the structure of a coin with the device according to the invention is shown in a cross-section representation. Equal components and components with equal meaning are given equal reference symbols.

Again, on a substrate 2 an RFID chip 3 and an antenna (not shown here in more detail) are arranged. A matching circuit 11 is also arranged on the substrate.

The RFID transponder is arranged with the substrate 2, the chip 3 and the matching circuit within a recess 5 of the coin body 6.

To fix the substrate within the recess 5, an epoxy adhesive mass 30 is arranged on the underside of the substrate, opposite a metallic base body 6a of the coin body 6. Alternatively or additionally, further metal layers can be arranged between the substrate 2 and the metallic base body 6a. A conductive adhesive mass 31 is arranged circularly on the metallic base body 6a on the underside in the round coin 6, so that in this way electrical contacting with the metallic base body 6a as a second electrically conductive surface element is obtained. For this purpose, a connection surface 32, which is preferably in annular form, and is arranged on the underside of the substrate 2, is also used.

On its top side, the substrate has a further connection surface 33, which is preferably arranged annularly, and which is in electrical contact by means of electrically conductive adhesive elements 34, which are preferably in annular form, with sections 35 in annular form of the first surface element 7, which acts as a capacitor surface, and which also represents the cover of the coin body.

The first surface element 7 is electrically insulated from the second surface element 6a, which also acts like a plate capacitor, by an insulating element 13, preferably in annular form.

In the assembly, the RFID inlet substrate 2 is stuck to the second surface element 6a, and also within the coin body 6, by means of epoxy adhesive mass 31, and thus mechanically fixed. Simultaneously, by means of a conductive adhesive, an electrical connection between the chip 3 and the surface element 6a of metallic material is produced. A combination of an epoxy adhesive and a conductive adhesive thus exists, and permits not only mechanical fixing, but also electrical contacting of the RFID inlet to the metallic base body. After the RFID inlet is installed in the metallic base body 6, the metallic body or the coin 6 is closed at the top by the surface element 7. Both the fixing of the surface element 7 and the connection to the matching circuit 11 are again achieved by means of epoxy adhesive and conductive adhesive masses 34.

Alternatively, other contacting methods such as contact springs, screwed connections, soldered connections and similar connections can be used for contacting the RFID transponder with the first and second surface elements 6a, 7 arranged on the top and underside.

The insulating element 13 is implemented by a plastic insert or by pouring, e.g. dispensing, the insulating mass into the filling space between the side walls of the coin body 6 and the cover 7.

All features which are disclosed in the application documents are claimed as essential to the invention if they are novel compared with the prior art, individually or in combination.

### REFERENCE SYMBOL LIST

1 RFID transponder

2 substrate

3 RFID chip

5 recess

6, 7 object

6a, 8 second surface element

7, 14 surface element

9, 34 connecting element

10, 31 second connecting element

11 circuit

12, 22 capacitor

13 insulating element

14 surface element

15, 15a fourth surface element

8, 6; 15, 15a surface elements

16 coin body

16, 17 connecting lines

18 reader

19, 19a, 20 gap

21, 25 resistor

24 power supply

26, 28 chip connection surface

26 contact surface

27, 34 adhesive elements

29 double arrows

31 adhesive mass

32 second connection surface

33 first connection surface

35 sections

1. RFID transponder device with at least one substrate and at least one RFID chip, comprising:
at least one electrically conductive first surface element, which is at a distance from the substrate and connected electrically to the substrate and/or the RFID chip by at least one electrically conductive first connecting element, and
at least one electrically conductive second surface element, which is at a distance from the substrate and connected electrically to the substrate and/or the RFID chip by at least one electrically conductive second connecting element, wherein
the second surface element is electrically insulated from the first surface element by at least one insulating element,
the first surface element and the second surface element are each part of an electrically conductive wall of a closed metal housing of an object, and are each used as a capacitor surface of two capacitors, and
the substrate and the RFID chip are arranged within a recess of the object.

2. RFID transponder device according to claim 1, wherein the second surface element is part of the object which envelops the substrate, and the first surface element covers the recess of the object, the substrate and the RFID chip being arranged in said recess.

3. RFID transponder device according to claim 2, wherein the object which at least partly envelops the substrate is a coin.

4. RFID transponder device according to claim 1, wherein the first surface element is insulated electrically from the second surface element by an insulating element in annular form.

5. RFID transponder device according to claim 4, wherein the insulating element is formed by a plastic insert or by pouring an insulating mass into a filling space between the walls of the body and a cover.

6. RFID transponder device according claim 1, wherein an underside of the metal housing acts as the second electrically conductive surface element, and a top side of the metal housing acts as the first electrically conductive surface element.

7. RFID transponder device according to claim 1, in communication with a reader having:
at least one third surface element and one fourth surface element, which are arranged opposite each other in such a way that the third surface element is at a first distance from the first surface element of the RFID transponder device, to form a capacitive coupling between the first and third surface elements, and the fourth surface element is at a second distance from the second surface element of the RFID transponder device, to form a capacitive coupling between the second and fourth surface elements, to make a capacitive coupling possible for contactless transmission of data between the reader and the RFID transponder, by
the first surface element and the second surface element each being part of an electrically conductive wall of a closed metal housing of an object, and each acting as a first capacitor surface of two capacitors, and
the third surface element and the fourth surface element each acting as a second capacitor surface of the two capacitors.

8. Method for producing an RFID transponder device, with at least one substrate and at least one RFID chip, comprising the following steps:
arranging the substrate and the RFID chip within a recess in an object,
electrically connecting a first connection surface, which is arranged on the substrate and connected to a first chip connection surface, to an electrically conductive first element which is at a distance from the substrate of the object,
electrically connecting a second connection surface, which is arranged on the substrate and connected to a second chip connection surface, to an electrically conductive second element which is at a distance from the substrate of the object,
electrically insulating the second surface element from the first surface element by at least one insulating element, and
the first surface element and the second surface element each being part of an electrically conductive wall of a closed metal housing of an object, and each acting as a capacitor surface of two capacitors.

9. Method according to claim 8, with a step of arranging an inductively and/or capacitively acting circuit on the substrate, the circuit being connected electrically to the first chip connection surface and the first connection surface of the substrate.

10. Method according to claim 9, wherein
the step of arranging an inductively and/or capacitively acting circuit on the substrate, the circuit being connected electrically to the first chip connection surface and the first connection surface of the substrate.

11. Method according to claim 9, wherein
between the first and second surface elements, at least one electrically insulating element is arranged.

12. Method according to claim 9, wherein
the step of testing the functionality of the assembly of the substrate and RFID chip and the first and second surface elements by a reader for reading the data stored on the RFID chip, said reader being connected to at least one third surface element and at least one fourth surface element.

13. Method according to claim 12, wherein
the third surface element is at a first distance from the first surface element, and together forms a capacitive coupling, and the fourth surface element is similarly at a second distance from the second surface element, and together forms a capacitive coupling.
